(19) United States
(12) Patent Application Publication
(10) Pub. No.: US 2014/0292393 A1
(43) Pub. Date: Oct. 2, 2014

(54) GATE VOLTAGE GENERATING CIRCUIT

(71) Applicant: ADVANCED POWER ELECTRONICS CORP., Zhubei City (TW)

(72) Inventor: Cheng-Wen Chang, Zhubei City (TW)

(73) Assignee: Advanced Power Electronics Corp., Zhubei City (TW)

(21) Appl. No.: 13/853,454

(22) Filed: Mar. 29, 2013

(51) Int. Cl. H03K 17/04

(52) U.S. Cl. CPC H03K 17/04
USPC 327/376

(57) ABSTRACT

A gate voltage generating circuit to provide a gate voltage to a transistor switch is disclosed. The gate voltage generating circuit includes a first voltage generating circuit and a second voltage generating circuit. The first voltage generating circuit supplies a first voltage to a gate electrode of the transistor switch. The second voltage generating circuit supplies a second voltage to the gate electrode of the transistor switch. The second voltage is larger than a voltage to turn on the transistor switch. The first voltage is larger than the second voltage.

### TECHNICAL FIELD

The present disclosure relates to a voltage generating circuit, and more particularly to a gate voltage generating circuit.

### BACKGROUND

Typically, a gate voltage generating circuit is connected to a gate electrode of a transistor switch for turning on/off this transistor switch, such that the gate voltage generating circuit supplies a high level voltage to turn on the transistor switch. A charge pump circuit is usually used as the gate voltage generating circuit. The charge pump circuit may supply a specific voltage higher than the voltage required to turn on the transistor switch, so as to keep pulling down the resistance between a drain electrode and a source electrode of the transistor switch and reduce the power consumption.

However, prior to accessing the charge pump circuit, a period of charging time is needed to charge the charge pump circuit in order to reach a voltage to turn on the transistor switch. Such charging time is a bottleneck of whether an electrical apparatus is ready for instant use.

### SUMMARY

The present invention discloses a gate voltage generating circuit to provide a gate voltage to a transistor switch. The gate voltage generating circuit comprises a first voltage generating circuit and a second voltage generating circuit. The first voltage generating circuit supplies a first voltage to a gate electrode of the transistor switch. The second voltage generating circuit supplies a second voltage to the gate electrode of the transistor switch. The second voltage is larger than a voltage to turn on the transistor switch. The first voltage is larger than the second voltage.

In an embodiment, the first voltage generating circuit is a charge pump circuit. The first voltage generating circuit further comprises a first diode. An anode of the first diode couples with the charge pump circuit. The cathode of the first diode couples with the gate electrode of the transistor switch.

In an embodiment, the second voltage is generated by a power supply. The second voltage generating circuit further comprises a second diode. An anode of the second diode couples with the second voltage. The cathode of the second diode couples with the gate electrode of the transistor switch.

Accordingly, the second voltage is generated by a power supply circuit. There is no charging time required for charging the second voltage generating circuit to generate the second voltage. Therefore, the switching velocity is enhanced. Moreover, the first voltage from the first voltage generating circuit is larger than the second voltage, so that, after the transistor switch is turned on, the resistance between a drain electrode and a source electrode of the transistor switch is pulled down to reduce the power consumption.

### BRIEF DESCRIPTION OF THE DRAWINGS

In order to make the foregoing as well as other aspects, features, advantages, and embodiments of the present disclosure more apparent, the accompanying drawings are described as follows:

FIG. 1 is a schematic diagram of a gate voltage generating circuit in accordance with an embodiment of the present invention.

FIG. 2 is a detailed circuit structure of the gate voltage generating circuit in accordance with an embodiment of the present invention.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

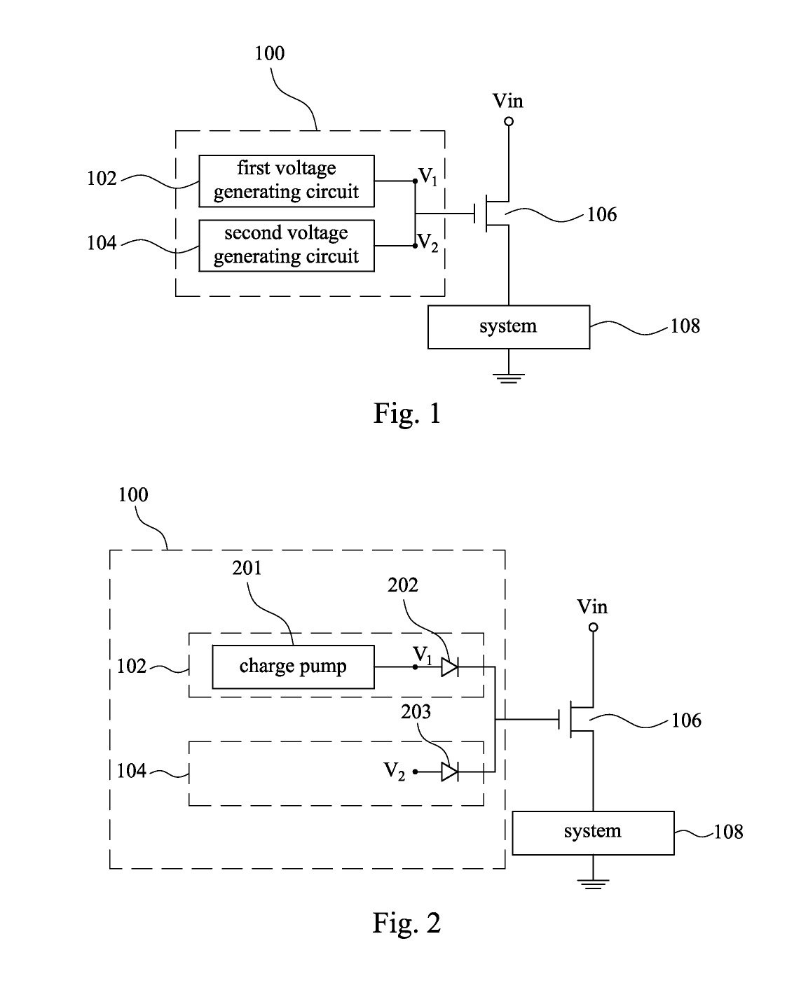

FIG. 1 is a schematic diagram of a gate voltage generating circuit in accordance with an embodiment of the present invention. The gate voltage generating circuit 100 supplies a first voltage V1 and a second voltage V2 to a gate electrode of a transistor switch 106 to turn on the transistor switch 106. When the transistor switch 106 is turned on, an operation voltage Vin is supplied to the system 108 through the transistor switch 106. The gate voltage generating circuit 100 comprises a first voltage generating circuit 102 and a second voltage generating circuit 104. In an embodiment, the first voltage generating circuit 102 is a charge pump circuit to supply a first voltage V1 to the gate electrode of the transistor switch 106. The second voltage generating circuit 104 supplies a second voltage V2 to the gate electrode of the transistor switch 106. The second voltage V2 is one of voltages generated by a power supply circuit and larger than a voltage to turn on the transistor switch 106. The first voltage V1 is larger than the second voltage V2, so that after the second voltage V2 turns on the transistor switch 106, a higher voltage, the first voltage V1, is supplied to the gate electrode of the transistor switch 106. If the transistor switch 106 is a N-type transistor switch, after the transistor switch 106 is turned on by the second voltage, a higher voltage, the first voltage V1, is continuously supplied to the gate electrode of the transistor switch 106, so that the resistance between a drain electrode and a source electrode of the transistor switch 106 is pulled down and the power consumption of the transistor switch 106 is reduced.

In this embodiment, the second voltage is generated by a power supply circuit. There is no any charging time needed to charge the second voltage generating circuit 104 to generate the second voltage to turn on the transistor switch 106. Therefore, the switching velocity of the transistor switch 106 is enhanced. Moreover, after the transistor switch 106 is turned on by the second voltage V2, the first voltage V1 higher than the second voltage V2 generated by the first voltage generating circuit 102 is continuously supplied to the gate electrode of the transistor switch 106, so that the resistance between a drain electrode and a source electrode of the transistor switch 106 is pulled down and the power consumption of the transistor switch 106 is reduced.

FIG. 2 is a detailed circuit structure of the gate voltage generating circuit in accordance with an embodiment of the present invention. The gate voltage generating circuit 100 comprises a first voltage generating circuit 102 and a second voltage generating circuit 104. In an embodiment, the first voltage generating circuit 102 includes a charge pump circuit 201 and a first diode 202. An anode of the first diode 202 couples with the charge pump circuit 201. The cathode of the first diode 202 couples with the gate electrode of the transistor switch 106. The charge pump circuit 201 generates the first voltage V1. The first voltage V1 is supplied to the gate electrode of the transistor switch 106 through the first diode 202. The second voltage generating circuit 104 comprises a second diode 203. The second voltage V2 generated by a power supply circuit (not shown in this FIG. 2) is supplied to the second diode 203. An anode of the second diode 203 couples with the second voltage. The cathode of the second diode 203 couples with the gate electrode of the transistor switch 106. The second voltage V2 is supplied to the gate electrode of the transistor switch 106 through the second diode 203. The first diode 202 may prevent a current generated by the second voltage V2 flowing into the charge pump circuit 201. The second diode 203 may prevent a current generated by the first voltage V1 flowing into the position coupling with the second voltage.

Accordingly, the first voltage generating circuit and the second voltage generating circuit are adopted to supply the gate voltage of the transistor switch. The second voltage from the second voltage generating circuit is generated by a power supply circuit. There is no any charging time needed to charge the second voltage generating circuit to generate the second voltage to turn on the transistor switch. Therefore, the switching velocity of the transistor switch is enhanced. Moreover, the first voltage generated by the first voltage generating circuit is higher than the second voltage. The first voltage is continuously supplied to the gate electrode of the transistor switch after the transistor switch is turned on, so that the resistance between a drain electrode and a source electrode of the transistor switch is pulled down and the power consumption of the transistor switch is reduced.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A gate voltage generating circuit for providing a gate voltage to a transistor switch, comprising:
a first voltage generating circuit for supplying a first voltage to a gate electrode of the transistor switch; and
a second voltage generating circuit for supplying a second voltage to the gate electrode of the transistor switch, wherein the second voltage is larger than a voltage to turn on the transistor switch and the first voltage is larger than the second voltage.

2. The gate voltage generating circuit of claim 1, wherein the first voltage generating circuit is a charge pump circuit.

3. The gate voltage generating circuit of claim 2, wherein the first voltage generating circuit further comprises a first diode, wherein an anode of the first diode couples with the charge pump circuit and a cathode of the first diode couples with the gate electrode of the transistor switch.

4. The gate voltage generating circuit of claim 1, wherein the second voltage is generated by a power supply circuit.

5. The gate voltage generating circuit of claim 4, wherein the second voltage generating circuit further comprises a second diode, wherein an anode of the second diode receives the second voltage and a cathode of the second diode couples with the gate electrode of the transistor switch.
